(19) United States
(12) Patent Application Publication
(10) Pub. No.: US 2002/0138226 A1
(43) Pub. Date: Sep. 26, 2002

(54) Software load tester

(76) Inventor: Donald Doane, River Edge, NJ (US)

Correspondence Address: Thomas J. McWilliams, REED SMITH LLP, 2500 One Liberty Place, 1650 Market Street, Philadelphia, PA, 19103-7301, US

(21) Appl. No.: 09/817,750

(22) Filed: Mar. 26, 2001

(51) Int. Cl. G01R 31/00; G06F 19/00

(52) U.S. Cl. 702/119

(57) ABSTRACT

A software load tester, and a method of software load testing, are disclosed. The load tester includes a remote access connection to at least one provider, wherein the remote access connection is accessible to at least one remote user and to at least one remote site, a plurality of load test resources resident at the at least one provider, and at least one account recorder that governs access by the at least one user to said plurality of load test resources, such as by requiring username, a password, an account code, an encryption key, or cookies. The method includes the steps of remotely connecting at least one provider to at least one remote user and to at least one remote site, providing a plurality of load test resources resident at the at least one provider, governing access by the at least one user to the plurality of load test resources, and load testing the at least one remote site upon receipt of a direction to load test from the at least one remote user granted access according to the governing of access.

### CROSS REFERENCE TO RELATED APPLICATIONS

Not Applicable.

### STATEMENT REGARDING FEDERALLY SPONSORED RESEARCH OR DEVELOPMENT

Not Applicable.

### BACKGROUND OF THE INVENTION

Field of the Invention

The present invention is directed generally to a performance monitor, tester, recorder, and report generator for a site that displays information, such as a web-site and, more particularly, to a remote-based load tester implementation that allows the user to utilize any browser-based interface to conduct and monitor performance testing of a site under load, from any location and at any time, while enabling the provider of the load tester service the ability to monitor, manage, and bill users of the site tester for their usage.

2. Description of the Background

Load testing tools have become very useful in the Internet economy for the testing of sites under use conditions. Load testing tools generally provide realistic volumes of simulated users in order to measure, define, validate, predict, and maintain optimal web-site application performance. Businesses are aware that a poor quality web-site may actually do financial harm to the business or a related enterprise. A potential customer on a web-site may leave the web-site if the site does not respond quickly or appropriately to the customer with page updates, interactive information, or appropriate links to relevant information. Poor quality interactions with customers may be caused by servers unable to respond to peak traffic demands, hung, stalled or slow web-applications, broken or non-responsive links, service provider faults, errors induced by mis-matched platforms or applications, or even by customer-generated errors. Whatever the source of the fault or bottleneck, the potential customer on a poorly performing web-site may quickly become frustrated and abandon the user session. Additionally, a potential or established customer to a web-site may abandon the product or service and not return due to a poor interface. Naturally, this adversely affects business revenue.

Given the direct dependencies between web-site performance and business revenue, it is prudent to perform web-site testing, in both the developmental stages of a site development and post deployment stages in order to ensure a top quality third-party web-user or customer experience. Web-enabled enterprises must be conscious of the fact that, in order to allow for business growth, site applications and resources must not only perform well when deployed, but must also be scalable so that additional demand by customers is met easily.

Many businesses view the Internet as either a supplemental or as a primary source for collecting new business. Just as many small, start-up, or expanding businesses lack the technical expertise to develop web-sites without outside aid, and therefore contract these services out to experienced web developers, similarly, web-site developers may not have the skill or resources to develop web-test tools. Such web-testing tools have become a clear test for determining whether a web developer has generated a product that is ready for deployment. Thus, pre-deployment testing, including load testing, becomes paramount to initial success. Software loading tools can be used not only to test performance, but also to provide a baseline parametric standard against which performance objectives can be objectively measured. Thus, monitoring and other post-deployment testing results contribute greatly to the determination of whether future growth needs can be accommodated and may serve as a technical performance check-up to manage system capacity and resources, as well as to preserve continued success. Thus the suppliers of e-business infrastructure, such as web-site developers, ISPs (Internet Service Providers), ASPs (Application Service Providers), and MSPs (Management Service Providers), have a need for web site testing which includes load testing, monitoring, and performance management.

Historically, software load and performance testing has been accomplished on sites by hosting the load testing and performance monitoring software on dedicated servers that service the web site application software. These servers are generally co-located with the web site application software. This co-location limitation serves only to restrict access from the end-user of the load test service, meaning that this co-location restricts prospective users by forcing those users to purchase load testing from a third party, and then have that third party design and perform test. Simulated user loads are generally developed via a separate coding by testing technicians, or by recording actual traffic and extracting that “hit” traffic to create load profiles. Those load profiles are then run within the load software to simulate actual user-to-website activity. Generally, load can then be incrementally increased in a linear fashion to simulate higher numbers of real-world users, thereby assessing the maximum load under which the site hardware and application software are capable of performing. However, actual site traffic may be non-linear in nature and may be more closely modeled as an exponential function. It is also not uncommon to have load test software combine multiple transaction types, as well as varied real world user connection speeds, and randomized real world user “think times” and responses, included in the load simulation. Other common features of load testing include, for example, recording and playback of performance measuring sessions, bottleneck identification, and business impact modeling. During a web-site load simulation, an assessment of the performance of the web site as seen from the real-world user perspective is attempted. Generally, for example, specific areas of the web site application are assessed and reported to the test conductor. The test conductor can then report the test results to the web site developer to enable the developer to engage in web site application tuning. Again, the end-user of the site testing service must wait until a report is compiled by the test conductor before results of the testing are mailed to him. Instant results are generally not available.

Consequently, there is an access limitation present in most load testers, because of the need for support staff to either code the parameters of the test loads, run the tests, and/or report the results to a web developer or other end-user. Therefore, the need exists for a load tester that can be run from anywhere, anytime, to test all features of a web application, and that can be operated under more realistic, i.e. non-linear, conditions. Further, a need exits for a load tester that is decentralized, in order to free up the valuable resources for the tasks of configuring, scheduling, executing, recording, and reporting on load tests for customers.

### BRIEF SUMMARY OF THE INVENTION

The present invention is directed to a software load tester. The load tester includes a remote access connection to at least one provider, wherein the remote access connection is accessible to at least one remote user and to at least one remote site, a plurality of load test resources resident at the at least one provider, and at least one account recorder that governs access by the at least one user to said plurality of load test resources, such as by requiring username, a password, an account code, an encryption key, or cookies. The load tester may additionally include a use-recorder that records activity on the at least one remote site by the at least one user granted access to the at least one remote site according to the account recorder. The recorded activity then becomes at least one of the plurality of load test resources, and may be played back or edited.

Additionally, the load tester may include a load test manager. The user enters a plurality of load test information into the load test manager in order to execute at least one load test using said plurality of load test resources. The load tester may also include a scheduler that schedules access by a plurality of users to the plurality of load test resources, and a performance appraiser that outputs a plurality of performance characteristics of the remote site that is subjected to the plurality of load test resources.

The present invention is also directed to a method of software load testing. The method includes the steps of remotely connecting at least one provider to at least one remote user and to at least one remote site, providing a plurality of load test resources resident at the at least one provider, governing access by the at least one user to the plurality of load test resources, and load testing the at least one remote site upon receipt of a direction to load test from the at least one remote user granted access according to the governing of access. The method may additionally include the steps of recording and playing back user scenarios, scheduling use of the load tester, and appraising performance of the at least one remote site.

The present invention solves problems experienced in the prior art by providing a load tester that can be run from anywhere, anytime, to test all features of a web application, and that can be operated under more realistic, such as non-linear, conditions. Further, the load tester of the present invention is decentralized, and thereby frees-up valuable resources for the tasks of configuring, scheduling, executing, recording, and reporting on load tests for customers.

### BRIEF DESCRIPTION OF THE SEVERAL VIEWS OF THE DRAWINGS

For the present invention to be clearly understood and readily practiced, the present invention will be described in conjunction with the following figures, wherein:

FIG. 1 is a depiction of a remote access load tester system configuration;

FIG. 2 is a depiction of the login module software flow that is utilized in the system of FIG. 1;

FIG. 3 is a depiction of the of the user scenario recording module software flow;

FIG. 4 is a depiction of the user scenario editing module software flow;

FIG. 5 is a depiction of the user scenario playback module software flow;

FIG. 6 is a depiction of the Delete User Scenario Module software flow;

FIG. 7 is a depiction of the test scenario manager module software flow;

FIG. 8 is a depiction of the Test Scenario scheduling module software flow diagram;

FIG. 9 is a depiction of the reporting Module software flow; and

FIG. 10 is a depiction of the Account Administration Module software flow.

### DETAILED DESCRIPTION OF THE INVENTION

It is to be understood that the figures and descriptions of the present invention have been simplified to illustrate elements that are relevant for a clear understanding of the present invention, while eliminating, for purposes of clarity, many other elements found in a typical web-browser based software utility. Those of ordinary skill in the art will recognize that other elements are desirable and/or required in order to implement the present invention. However, because such elements are well known in the art, and because they do not facilitate a better understanding of the present invention, a discussion of such elements is not provided herein. Additionally, the following definitions are provided to aid in understanding the usage of terms employed in this specification:

System User: A system user represents an individual that is authorized to use the load test software system for its load test, analysis, reporting, and other utility functions. A system user is an account-based program user.

Real-World User:A real-world user is an individual who is a customer or prospective customer to a system user, that may access a web-site or other site in contemplation of any type of e-commerce transaction with a system user for products or services.

Simulated User:A simulated user is a software entity that mimics the interactions of a real-world user.

During a load test, the system is capable of generating hundreds or thousands of simulated users to the Site under test. A simulated user can be represented by either a simulated transaction or a pre-recorded real-world user played back to simulate a software load.

User Scenario: A user scenario represents a series of interactions between a simulated user and a site. User scenarios can be recorded, edited, played back and deleted by a system user.

Test Scenario: A test scenario determines the makeup and configuration of a test. It includes weighted user scenarios, browser types, connection speeds and other configurable parameters. A system user must schedule a test scenario through the System in order to run a load test against a site of interest.

Remote Access: Remote access may be defined as that type of access which is not hard-coupled and proximate to a provider of the load testing service. Remote access may be characterized as being any of the following: multiple user oriented, requiring a protocol-governed interface, or requiring recognition and authentication of the remote user via such techniques as Login utilizing user names or identifications, passwords, encryption techniques, or specific protocol usage. Examples of remote access interfaces can be found in centralized or distributed systems where multiple users access the target via a network type of connection (LAN, WAN, Internet, Intranet, or other network), using any type of interconnection technology (wire or cable; metal wire, optical fiber, or wireless; RF, infrared, acoustic, optical freespace or other).

Page: A page represents a displayable screen containing, at least in part, information and functionality for the application. Examples of standard mechanisms for function selection on a page would be point and click, radio buttons, drop down menus, hyperlinks, etc.

System: The term system refers to the software load testing system described herein, including the GUI, load simulators (Test loads), and software applications to manage the resources (both hardware and software) of, and to report on, load testing activities supplied by providers.

Site: A Site is displayed information, generally programmed to be capable of interactive communication with the operator of the device on which page is being displayed. However, a page may also display merely information content. A Site may be accessed via an appropriate connection to a network of any topology or may be hard-wired to a set of local computing and/or display resources. Examples of Sites are Internal or External Web-sites located anywhere, being in the development, deployed, on-line, or off line state.

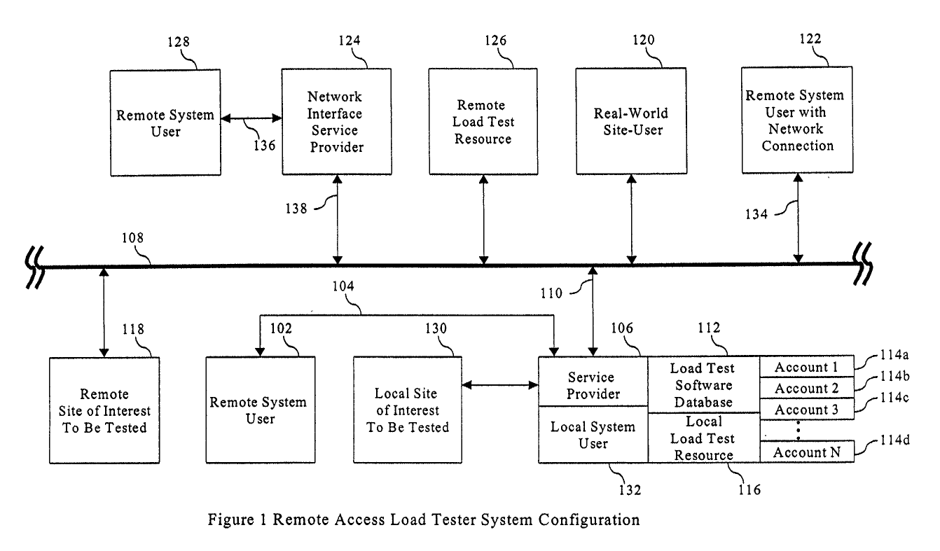

FIG. 1 is a block diagram illustrating a remote access load tester system. The system includes at least one remote system user 102, a remote access connection 104, a provider 106, such as a third party service provider, having resources for load testing, including, but not limited to, a load test software database 112, and a local load test resource 116, and having accounts 114a-d, of which at least one account 114a-d is established for use by the remote system user 102, and which accounts are preferably subject to log-in accessibility by at least one of the plurality of remote users 102. Preferably, the architecture additionally includes at least one Site that is to be tested either locally to the provider 130, or that is remotely 118 accessible via a network 108 and a network connection 110.

A remote system user 102 is a user having access to a remote access connection 104, and preferably having a desired site to be tested, defined herein as a site of interest. A remote system user is a system user, as defined hereinabove, that accesses the system of use via a remote access connection 104. A remote system user preferably has log-in accessibility to at least one account 114 a-d of the provider 106, which account preferably provides access to the load testing resources 112, 116, as discussed further hereinbelow. The login process is discussed hereinbelow.

A remote access connection 104 is an interconnect or a series of interconnects which allow communications between at least a remote system user 102 and another entity, such as a provider 106, for example. The remote access connection 104 may be any type of connection to, for example, a network such as a LAN, WAN, Internet or Intranet, via any method known in the art, such as via a hard connection using wire, cable, optical fiber or cable, or other hard wired connection type, or via a wireless connection using optical, infrared, acoustic, RF, Laser or other wireless connection type, or via a modem connection, or via any other standard network connection technique, such as Ethernet, Appletalk, Sonet, SDH, direct private connection, or the like, wherein the connection is compatible with the network protocol needed to establish communication with the network 108 or direct connection on which the provider 106 resides. The numerous types of networks and remote connections to those networks will be apparent to those skilled in the art. The load tester of the present invention can be run from any location, not just at the host/server location of the provider, because the load tester may be executed from any device having a remote access connection 104, such as any web-enabled device communicating with the internet, including hand held devices connected to an internet socket.

Examples of network connections allowing remote users access to the load test resources 112, 116 are at network connection points 110, 134, and 138. An example of a separate remote access connection is also given at connection point 104. In the present invention, the remote system user 102 has a remote access connection 104 to the provider 106. In the present invention, the remote system user access connection 104 may be via a wire, cable, wireless interface or equivalent thereof, as discussed hereinabove, capable of interconnecting one or multiple users 102 to the provider 106, such as via the network 108 or via a direct connection. Alternatively, a remote system user 128 may gain access to the provider 106 via an interface 136 to a network interface service provider 124 that supplies interfaces, protocols, and services to interface to a backbone network 108 via a network interface 138. Alternatively, a remote system user 122 may be one who has a network interface 134 and need not utilize a network interface service provider. Each of these remote users 128, 122, 102, has remote access to a provider 106 that may supply access to load testing services on an account-driven basis.

The provider 106 may be, for example, a third party service provider that has licensed a copy or copies, or has licensed access to, the load test software database and load test resources. Alternatively, as used herein, the provider 106 may be the owner and/or manufacturer of the software used in the present invention, wherein the provider either licenses to another provider, or offers direct access to, the load testing software database and/or load test resources. The provider may be, for example, an ISP, ASP, or the like, and may maintain the load test software database and load test resources at the provider 106, or may have a remote link to the load test software database and/or load test resources, wherein the remote link may be substantially similar to the remote access connection discussed hereinabove.

The load test resources may be any load testing resources known to those skilled in the art, such as, but not limited to, those load testing methodologies discussed hereinbelow, and may additionally include the simple activation of a predetermined number of subscriber lines of the provider to access the site of interest. The load test resources may be resident, along with a load test software database, at the provider. In one preferred embodiment of the remote access load tester system, the remotely located access load test resources are located in different domains. The provider 106 may have local load testing resources 116 to provide simulated users as loads to the Site under test. Additionally, other load testing resources 126, which are located outside of the domain of the provider 106, via either physical placement or network addressability, may be incorporated to enhance the load testing capability of the load tester system. Further, in a preferred embodiment of the remote access load tester system, the Site under test 130, 118 need not be taken off-line from other users of the Site in order to be load tested. Thus, in a preferred embodiment, the access of real-world site-users 120 to the sites of interest 118, 130 need not be terminated for test execution purposes.

The present invention performs Site load and performance testing. The system user normally desires to utilize the testing, analysis, monitoring, recording, and or reporting features of the Load testing software in order to assess the performance of the site of interest. To that end, the system user preferably accesses an account with the provider, such as the ISP, ASP, Web-site developer, or other service-providing entity, in order to utilize the Load testing Services, as discussed hereinabove. Based on the authorization of access to the account, the system user can access the load testing software database/load test resources via a remote access connection (Internet, Intranet, private network, or other) , and program the parameters and schedule the execution of the load performance testing. Thus, to accomplish the programming of parameters and scheduling, the remote system user preferably first logs-in to the system in order to gain access to the system program and resources. The system is account-based, and may have numerous forms of security apparent to those skilled in the art, such as passwords, account codes, encryption keys, “cookies”, and the like, such that unauthorized users cannot gain access to the system. The account-based system entry also allows the provider to ascribe system use privileges to a particular account, as well as monitor the account for usage, and consequently for billing purposes, which performance of an account provider will be apparent to those skilled in the art, and which performance is substantially similar to account monitoring, allocation, and billing currently performed by ISPs and ASPs, for example. The provider may, for example, have certain users that are billed on a per use basis, certain users that are billed on a time basis, and certain users that are billed on a bulk use basis. Certain users may be billed according to resource usage, such as the number of simulated users and/or provider servers or machines that are used during a load test. Account administration is discussed further hereinbelow.

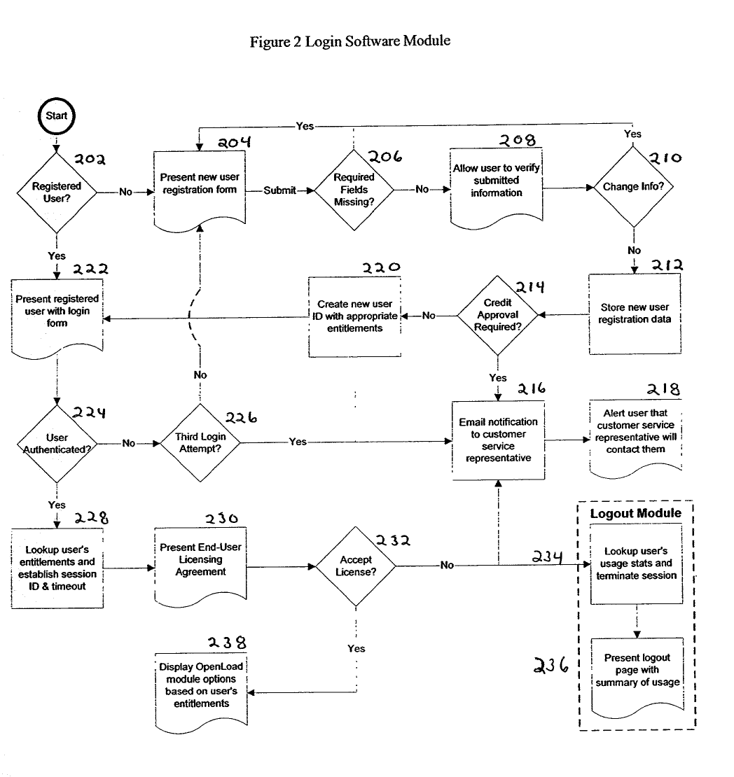

FIG. 2 is a flow diagram illustrating an exemplary embodiment wherein the system user attempts log-in to the account-based load test software to gain access to the load test resources. It is assumed that the system user navigates the remote access connection using a network interface, protocol, or procedure to gain access to the system login page, which is preferably resident at the provider, such that the system user can interact with a Login Software module. It will be apparent to those skilled in the art that the remote user must have a remote connection to the provider to effect log-in, as discussed hereinabove.

The login software module determines whether a system user is registered, authenticated, and/or entitled to use the system. This login software module incorporates the use of account-based access for the system user, and allows the service provider to monitor the usage of the system. For a registered system user, login may be accomplished via a single login page displayed to the system user, hereinbelow referred to as “the user”. FIG. 2 at step 202 prompts the user to type in either an existing username and password, or to register as a new user. If the user is not registered, then the new user is presented a New User Login Page 204, whereon the user enters a name and password or entry code, and may enter other information, such as a company address, the site of interest URL, voice and fax phone, e-mail address, desired username, and password. If any required fields are missing, the new user may be prompted for completion at step 206. The new user is then allowed to verify submitted information at step 208, and permitted to change it at step 210 before the module stores the new user registration data at step 212. A Registration Verification Page may be generated for this purpose, and may be displayed to the user. An assessment may be made at step 214 as to whether the new user requires credit approval before further utilizing the system functions. If credit approval is needed, then the user is alerted to that effect, such as by an e-mail message sent to the customer service representative at step 216, and an alert to the new user that the representative will contact the new user is displayed at step 218. An unapproved new user is prompted to exit the system.

If external credit approval is not required, the module generates a new user ID with a set of prescribed entitlements, i.e. prescribed privileges for system use, at step 220, and thereby approves the new user. The approved new user may then attempt to log into the system using the newly created login name and password at step 222. In the login authentication process step of 224, if the user, either registered or new, is rejected for cause, such as failure to enter a correct username and password three times at step 226, then a customer service representative may be alerted at step 216, and the unsuccessful user may be logged off at step 218. Assuming that the user has been successfully authenticated at step 224, the module accesses the successful user's entitlements and establishes a session ID and a timeout period, at step 228. The user is then preferably presented with a readable image of an End-User License Agreement to accept or reject at steps 230 and 232. Failure to accept the license agreement terminates the session at step 234 via a Logout Module that may present the user with a summary of usage at step 236. Acceptance of the License Agreement invokes a display of the load testing system options based on the users entitlements at step 238. The page displayed to the accepted user may include options for the user to select from, such as a series of tabs, buttons, icons, or links, allowing the user to, for example, logout, develop a user scenario, develop a test scenario, generate a report, or utilize the administrative functions.

Once remote access to the system is obtained by the system user, the system user can activate, create, modify, or delete load performance testing parameters, using system-to-user interfaces, such as a GUI, other software module, or the like. For example, the user can design the desired test using the load test resources, such as a non-linear test using a selected number of provider lines for a given duration accessing the site of interest, and can initiate the test design setup using a browser-based GUI over a web-based access page provided by the provider. This direct interaction with the system permits the system user to simulate the traffic effects that a plurality of real-world users would have on a system users' site of interest. This direct interaction may be gained, for example, though the use of a first page presented to an authenticated user, after selection of, for example, a tab, which first page enables the user to select either Record, Edit, Playback, or Delete functions of the user scenario, for example.

The system user can utilize Recording and Playback features, such as a Proxy Recording and Playback feature, in order to add real-world user authenticity to the test scenario. The Recording feature records the browsing of the site of interest that the system user directs, as the user visits the site of interest, or may record the browsing of several users of the site of interest, wherein the several users are either selected by the system user or the provider. It will be apparent to those skilled in the art that the privacy of third-party browsers must be maintained in the latter embodiment. The system user may, for example, access the site of interest via any script-based recorder, including web-supported features of WAP, SSL, Digital Certificates, Java Script, Flash, Video/Audio streaming, Applets, Frames, XML, as well as HTTP/HTTPS, FTP, SMTP, TCP/IP, and POP3, and exercise the features of the site, such as accessing links, audio files, video files, java displays, and the like, in a format that the system user assesses is indicative of the manner in which a real-world user would browse at the site of interest. The recording feature records this user scenario that is indicative of real-world user activity based on actual browser use by the system user on a site of interest. While recording, the system creates a log of such browser activity that may be displayed to the system user, either during or following the browsing. Load testing can then be accomplished by playing back the previously recorded browsing transactions of real-world like users on the target sites of interest, as discussed hereinbelow. Further, a database of such real-world uses may be created with respect to the site of interest, thereby allowing the load tester to access large numbers of different parametric real-use scenarios for each load test, which consequently more closely approximates the strain of real world performance for the site of interest. Alternatively, the browsing of actual browsers on the site of interest may be recorded for load test purposes, in an embodiment wherein at least a portion of the real-world traffic to the site of interest is transparently passed through the provider 106.

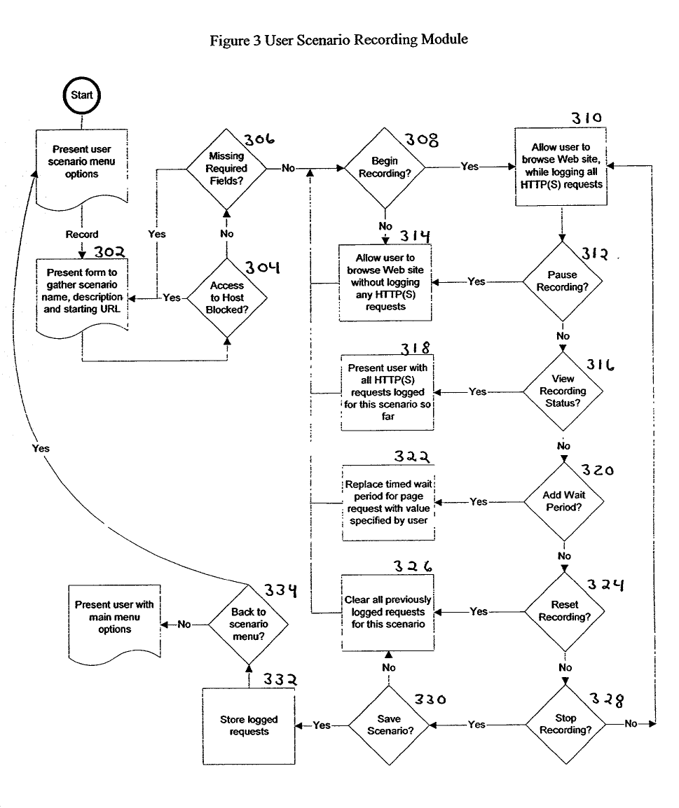

FIG. 3 is a flow diagram illustrating a Recording Module. The recording session illustrated may be utilized to record an actual browsing session of the site of interest as conducted by the user, as discussed hereinabove. Upon selection of the Record function, the user is presented with a display, the purpose of which is to gather user scenario name, description, and starting URL information at step 302. The user may enter a name for the recording scenario, a useful description, and a starting URL, for example. If access to the host computer or one of the required fields is missing, the user may be kept at the Recording Page, and errors displayed via steps 304, 306. Successful completion of the name, description, and URL enables the user to utilize functions, such as record, pause, status, wait, reset, and stop functions. The user may browse the Web site without logging any requests such as HTTP requests, even before actuating the record function. This may occur at step 314 by not asserting a record function at step 308. After deciding to actuate the record function at step 308, the user may browse the site of interest while recording the browsing at step 310.

The following are options which may be entered after the user initiates a recording of the session:

Pause—the user may pause the recording session at step 312 and continue to browse the web site at step 314.

Pause temporarily suspends recording, which may be resumed by a user selection.

View Recording Status—the user, after starting a recording session, may elect to view recording status which displays for the user all of the requests, such as HTTP requests, logged in the recording session at steps 316 and 318. This action effectively pauses, i.e. temporarily suspends, the recording session. After viewing the recorded requests, the user may resume browsing in the recording session. Upon resuming, the user will be returned to the last recorded URL;

Wait—during active browsing, the user may elect to add a Wait period at step 320 before the next request, as specified by the user at step 322. This action effectively pauses the recording session until the user resumes active browsing;

Reset—at step 324, the user may elect to reset the recording session and delete any recorded information from the present session by clearing all previously logged requests for the scenario at step 326; and

Stop—a stop selection by the user at step 328 will allow the user to further elect at step 320 to either save the session by storing requests at step 332, or clear the recording session at step 326. Saving a session will take the user back to the selections of the Recording Module or, for example, to Main Menu Options. The user makes this selection at step 334.

System users may customize the Recordings via a Log Editor, for example. This editor preferably allows the system user to easily modify the previously recorded browsing activity or activities, thereby enabling the system user to perform simulations based on real-world user browsing interactions or user browsing sessions, as described hereinabove. The log editor allows the system user to modify the browsing scenario without deleting and re-recording the browsing scenario. Thus, the system user is saved the difficulty of reprogramming and re-recording the browsing session if changes are desired. This is accomplished via the user scenario edit software module.

Multiple users may access the system and use the recording module and the user scenario. edit module, wherein an account is set up to authorize multiple users, and each browse the site of interest separately, either simultaneously or at different times, thereby creating a database of multiple real-world site users. Such a database may be divided by any predetermined user type, such as, for example, by fast browsers, i.e. parties that quickly move around a site, necessitating linking and activities at a high rate, mid-range browsers, and slow browsers.

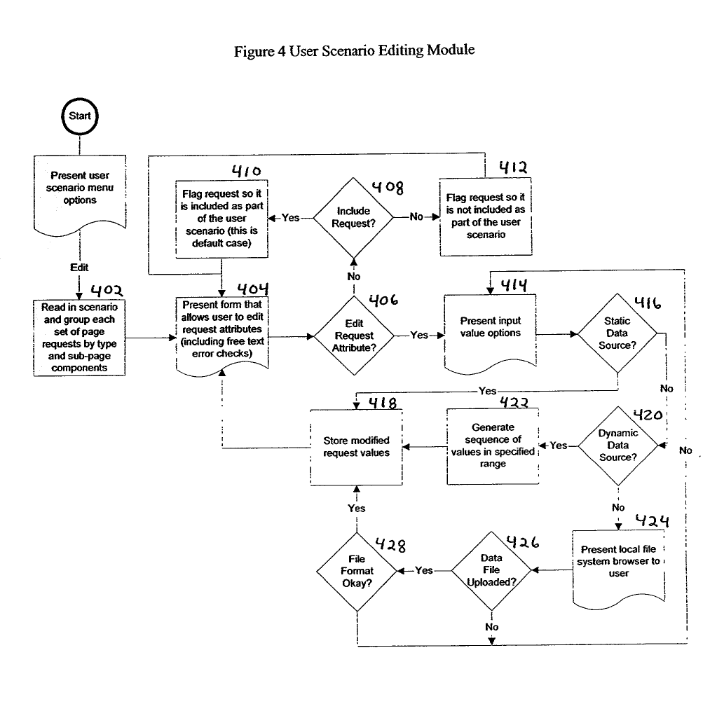

The user scenario edit module is entered via the User Scenario Edit function selection at the Main Menu. The purpose of the module is to present a page of information to the user in order to provide an easy to use interface for the editing of individual requests, such as HTTP requests, within a recorded browsing session contained within a user scenario. FIG. 4 is a flow diagram illustrating the user scenario edit software module. Upon entering the module, the module reads the user scenario at step 402, and formats the information for easy display and editing at step 404. Standard file open (+) and closed (−) symbology is displayed for use in the editing process. The user can edit a request at 406. The user can either include an individual request at steps 408 and 410, or exclude the request at steps 408 and 412. If inclusion is desired, the selection of inclusion is made at 408 and executed at 410. If inclusion is not desired, then the request is flagged as such in step 412. Upon either selection, the program brings the user back to the beginning of a new request edit at step 404. If the user decides to edit an attribute of the request, the software module may present input value options to the user for selection convenience at step 414. If it is a static data source, the request change is stored via steps 416 and 418. If it is a dynamic data source, the module generates a sequence of values in the specified range via steps 416, 420, and 422, before storing at step 418. At step 422, one possible editing prompt for dynamic information is the URL Editor. The URL editor is a display page which allow a user to edit a URL's attributes, including the query strings, cookies, and wait period. Name-Value pairs are also capable of edit. The system can generate default values for the user if the user enters an edit for such dynamic data sources. If it is neither a static nor dynamic data source, the module presents a local file browser to the user at step 424. The user may then select the file to upload via the browser interface of step 424, and up load the file at step 426. The file format is checked at step 428, and the new request file is stored via step 418. If no file is selected at step 426, the user is given present input value options from which to choose at step 414. The module is exited via a selectable function that ends the editing session.

After recording a user scenario, or after editing such a recorded user scenario, the system user can playback the recorded browsing session using the Playback feature, thus making possible a simulation based on the actual browser activity of an actual user of the site of interest. The system user can then dynamically see the specific browsing session activity represented in the editing log and verify that the recorded browsing session exercises the site of interest to the system user's full satisfaction.

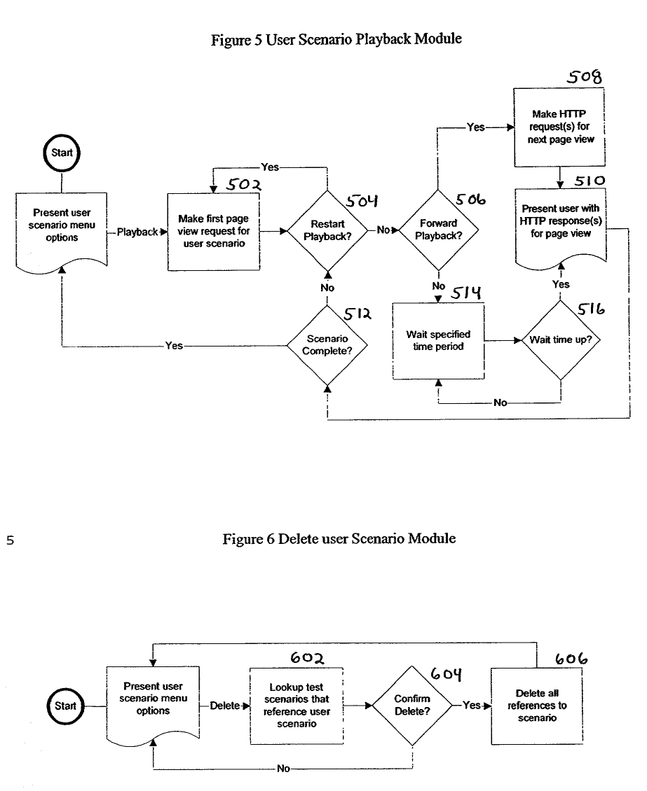

The Playback Software Module provides for the playback of a recorded user scenario. Playback allows the user to not only playback a recorded user scenario, but also to see its interaction in real-time with the site of interest. This allows a user to observe the recorded browsing, and thus generate potential edits to further tailor the browsing scenario prior to executing the test. In addition, the user may playback key portions of a conducted load test in order to observe the performance of a site of interest from a real-world user perspective. FIG. 5 is a flow diagram illustrating the playback feature. The user may initially select, for example, the User Scenario at a Main Page, and may subsequently select playback from the options. This selection may display the first Playback Page at step 502. The user has the option of starting playback, pausing, restarting, or rewinding the playback session at the page displayed at step 502. Wait time may be also specified for the playback session if desired. A decision to restart the playback may be made at step 504, which decision brings the user back to the first playback page. If, instead, a forward playback is selected at step 506, the module will continue the playback and display the next page request at step 508. The system responds by continuing the interactive playback at step 510 until the end of the scenario is determined at step 512. If the playback is not complete, the playback simply continues to termination, unless the user selects to pause or include a wait period at step 514. Upon expiration of the wait period at step 516, playback is resumed at step 510. The end of playback preferably brings the user back to the Main menu function selection page.

The Delete User Module displays a warning to user before the user permanently deletes a user scenario. The user may, for example, be alerted what other test scenarios will be affected by deleting a user scenario. The deletion module may be entered from the User Scenario function in the Main Menu page. FIG. 6 is a flow diagram illustrating a Delete User Module scenario. The module searches for user test scenarios that reference the user test scenario at step 602, displays the information to be deleted to the user for confirmation at step 604, and either deletes the information at step 606, or returns the user to the user scenario page.

The Load Test Scenario execution parameters are preferably fully programmable by the system user via remote access browser of any type. A software Test design module associated with the test scenario guides the system user to design the test of the site of interest to include various sets of parameters to produce a real-world test according to actual real-world user limitations. For example, the test scenario Test design module may guide the system user to select the browsing activities at arrival rates characterized by linear, exponential, or Poisson types of distributions. The system user can weight the types of simulated users produced by the load test software as, for example, new users, pre-registered users, and temporary visitors. The system user may select the distribution of simulated user tolerance levels to meet the expected tolerance level of real-world users. That is, the system user may select the percentage of total simulated users that are of high, medium, or low patience with site mis-performance. This allows the system user to determine what the drop-off rate of users is when a site starts to become overloaded by interactive requests. The characteristics of low, medium, and high tolerance levels may also be selected by the system user. The system user has a choice of selecting whether simulated users in each category can tolerate timeout times, page reloads or retries, number of unfound pages, number of times a server is busy, and the number of application faults, for example. Thus, the characterization of simulated users in each of the low, medium, or high patience or tolerance categories is fully definable by the system user so that intelligent simulation and reporting and analysis may be accomplished by the system. The system user may also configure other test scenarios to be conducted, with simulated users accessing the site of interest using access ports of different speeds. Here, ports may be a modem or network connections of any type that operate at different speeds. The system user can supply a percentage distribution to each individual port speed type to allow for different rates of simulated user browsing. The system user can also set up the weighted distribution of simulated user browser types to accommodate the real-world condition of different browsers and platforms utilizing the site of interest. Characteristics of different browsers may also be selected by the system user in the test scenario setup. The presence of cookies, java script, different protocols, keep-alives, pipelines, connection numbers, and SSLs are preferably selectable for each different browser type. A platform distribution of simulated users is also customizable by the system user. The system user may select the percentage distribution of platform types in a test scenario. It should be noted that the system user need not actually make any selections of parametric testing.

The intelligent test design module of the test scenario setup software selects rational default parameters for a system user. The system user has the choice of using these program-generated rational setup values, or customizing the load test to conform to the projected statistics of the use of the site of interest. Finally, the system user can determine the maximum load level, meaning the quantity, of simulated users, and the duration of the test to be conducted. These parameters of load quantities, duration, and other parameters can be tracked by the system accounting software to ascribe accurate billing and resource permission on a per system-user basis.

The test scenario manager software module allows the user to set up a test scenario to load and perform testing on a site of interest. The module preferably guides the user through the process of creating a new test. Initially, the module may pre-populate parametric test conditions into a test scenario, and then allow the user to customize those parametric conditions. These selectable parameters may include the number of users and the ramp-up of those users, simulated user scenarios, and weightings, simulated user response or “think times”, as well as tolerance levels, simulated user connection speeds, simulated user browser types and weightings, and simulated user Operating Systems.

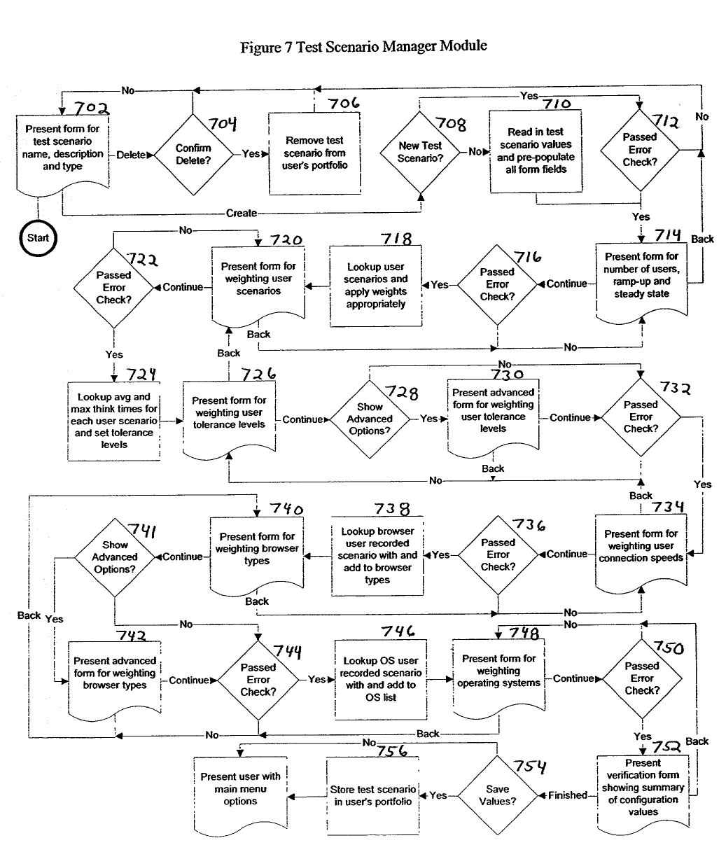

FIG. 7 is a flow diagram illustrating the Test Scenario Manager Module. Upon entry into the Test Scenario functionality from, for example, a Main Menu, a Manager Module may query the user for Test Scenario name, test type, and Test Description, at step 702. Previously saved test scenarios may be deleted at this time at steps 704 and 706. Creation of a new test scenario is the subject of the balance of the module at step 708. Upon selection of the creation of a new test scenario, the Test Scenario Manager Module may pre-load or pre-populate all fields in the test setup format at step 710, and check for errors at step 712. The module then queries the user for the number of users, the ramp up period, and the ramp up model rate of either linear, exponential, or Poisson distribution, along with the steady state period in a percentage of test duration in a Test Scenario Configuration at step 714. An error check is conducted at step 716. The module then looks for user scenarios, and applies the entered weighted values accordingly, at step 718. The user is then requested to modify the user weight for user scenarios at step 720. This allows the user to select the percentage of simulated user types in any one scenario, such as the percentages of new simulated users, registered simulated users, and simulated visitors. An error check is conducted at step 722, and the user is queried to modify the user think times and tolerance levels at step 724 and 726. More advanced options are offered at steps 728 and 730, and an error check is conducted at step 732. User modem connection speeds are then subject to modification by the user at step 734. An error check is conducted at step 736, and the user is queried as to browser types for simulated users at step 738, as well as a plurality of browser characteristics, such as the presence of cookies, java script, protocols, and keep-alives, for example. Advanced options for the weighting of browser options of simulated users are then preferably available for editing by the user at steps 740 and 742. Error checks may be conducted at step 744 before the user is queried as to simulated user Operating Systems and appropriate weightings at step 746 and 748. Such operating systems include Windows 2000, 98, 95, NT, and MacOS. Error checks at step 750 may then be conducted before the user is asked to review a summary of all of the configuration values at step 752 before the user is asked to save the values in step 754. The user may save the entered values in step 756 and then finally, the module exits to the main menu options. Additionally, percentages of simulated users that include the recorded real world browser or browsers from the recording module, including actual users of the site of interest that are referred through the provider for recording purposes, are also selected.

Using intelligent scheduling of the test scenario, the system user can schedule self-designed load tests to occur at any time that sufficient system resources are available. The user simply uses the Scheduling Test design module to enter the specific test scenario the user wishes to execute, with start and finish dates and times. The Load Tester provides the system user with resources, such as provider lines, and the allocation of available resources, such as provider lines, for testing located not only in the local domain of the service provider being subscribed to, but also allows external domain load testing resources to be utilized on a scheduled basis, such as by leasing. For example, a request that exceeds the available number of lines of the provider might allow the scheduling of lines to be leased from elsewhere, i.e. the scheduling of the purchase of excess capacity lines from outside parties, but those leased/purchased resources would still be integrated into the output of one test, and, as such, the use of the leased/purchased lines would be transparent to the user. Additionally, resources may be allocated such that no one server of the provider is over-burdened. For example, a requested test for the activation of 50,000 lines may be allocated as 10,000 each on 5 servers, or 5,000 lines each on 10 servers.

System users share system load test resources via this scheduling utility in the load testing software. The system checks not only local domain load test resources, but also networked outside domain load testing resources to determine if those resources are available for the proposed use and duration. If conflicts arise, the test design module provides modification of the requested scheduling options for the system user to consider before the system user attempts to reschedule a load test. This intelligent use of local and non-local domain test load resources, along with the availability of information for rescheduling options, provides a maximum of ease and flexibility for the system user to schedule a test. The test design module-driven software scheduler also allows a system user to confirm a schedule, modify a schedule, or delete a scheduled test. Once again, the account-based system properly tracks and limits as well as provides billing data for the users utilization of resources, local or other, to the system user via administration software. Thus, the purpose of the test scenario scheduler software module is to allow users to schedule a test scenario, or reschedule or stop a previously scheduled test scenario. The user may perform one of these actions on only one test scenario at a time. It should be noted that scheduling and test performance occur in real time and without human intervention using the present invention.

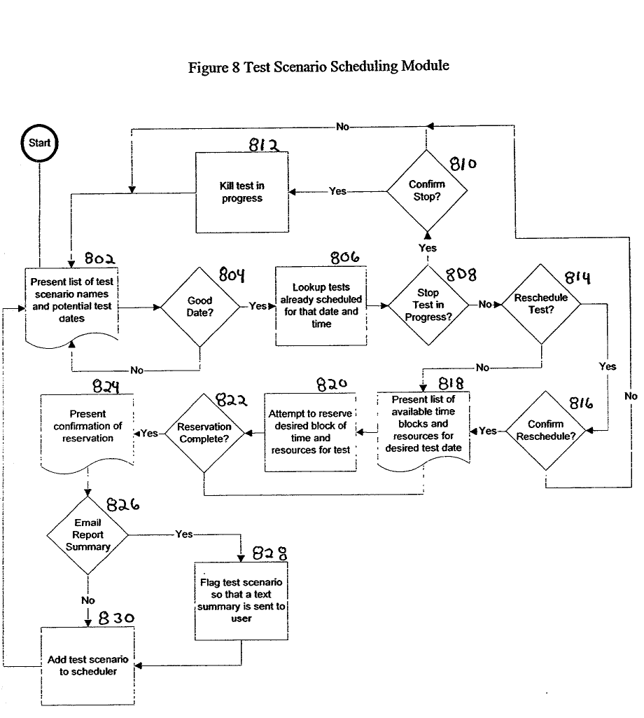

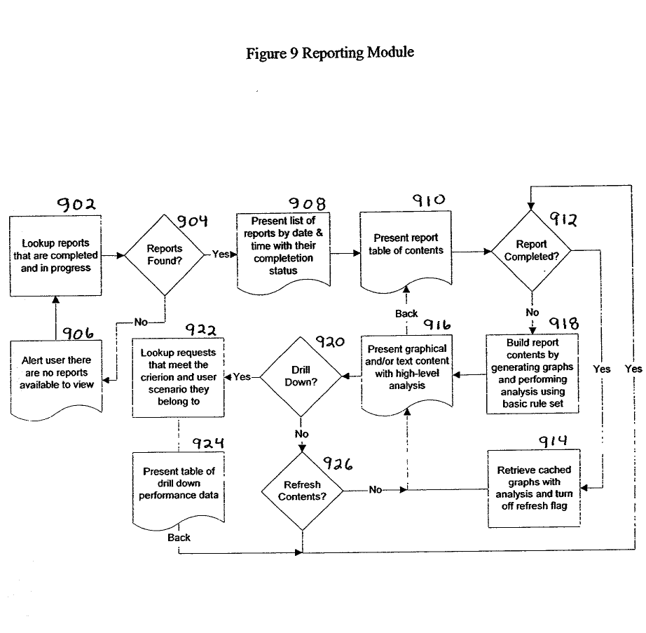

FIG. 8 is a flow diagram illustrating the Test Scenario Scheduling software module. Entry into the module occurs by selecting the Test Scenario function from the Main Menu, and then subsequently from the selection of the Scheduler function, for example. Once entry into the module is achieved, the module presents a list of the test scenario names and potential test dates at step 802. The user may specify a desired start and finish date and time for a selected scenario, and activates a schedule command function at step 804. A lookup function searches for tests already scheduled for that time period at step 806, to determine if a conflict is present to report to the user. Included in the Scheduler resources is a list of available locations that load testing will be generated from when the test scenario is run. To determine if a conflict is present, the scheduler must first query its own booking table, as well as that of other schedulers, in order to generate the list of available locations from which to run simulated user loads. A multiplicity of load sites may be selected to accommodate many load requests. If a test is already in progress, the test may be stopped at steps 808, 810, and 812 or rescheduled at steps 814 and 816. A list of rescheduling options, such as a date and time when resources are available, is presented to the user at step 818. A preliminary date and time selection is made by the module, which the user can change if desired at step 820. The user may accept the reservation at step 822. Confirmation of a reservation is made at step 824, and a report is sent to the user, via e-mail, indicating that a scheduling event has occurred, along with the details if desired 12 at steps 826 and 828. The newly scheduled test is added to the scheduler, and the user is prompted to continue scheduling more tests if desired at step 802. The module is exited via a stop function on the scheduler menu page.

System users preferably obtain performance reports from the testing performed via a browser interface, regardless of whether local or remote domain load test resources are used in a test. There is no need for service provider intervention to supply reports for user review. The report generated by the system integrates the system user's set-up to analyze the returned load test data, and to generate an intelligent reporting of load test results. The data generated preferably includes factors that contribute to poor site performance, and that data is preferably generated in real time. Additionally, data may include comparisons to previous load tests, thereby identifying improvements in performance or possible problems in performance. The data can preferably be viewed either tabularly or graphically, and analysis is provided by using the predefined rule sets. The data may be collected, analyzed and displayed in a variety of ways, some of which are apparent to those skilled in the art. Data may be viewed as a summary, including number of simulated users and session times, their tolerance response (e.g. annoyed, abandoned, etc.), their average request and response rates, and the pages reviewed, the number of simulated users versus page view times, the average round-trip response time as a function of simulated user type and pages viewed, the number of simulated users as a function of session time under load conditions, the number of users in annoyance versus abandonment under load conditions, the average request and response rates of the simulated users under load conditions, the number of active versus passive simulated user sessions under load conditions, the time of simulated users' connect versus response times under site load, the total data throughput as a function of loading profile as simulated users were added to the site, and the response time of DNS look-ups as a function of simulated user load. In addition, the reporting and analysis functionality of the system provides an accurate accounting of what factor in the site architecture was the limiting factor in total data throughput for each system user test scenario run.

The purpose of the reporting module is to manage the process of generating and retrieving reports of load test performance data. FIG. 9 is a flow diagram illustrating the Reporting Module. Entry into the module may be gained by activating the Reports functionality of the Main Page. The module then looks up reports for the specific user tests that are completed, or are in progress, at step 902. If no reports are found at step 904 the user is alerted at step 906. If reports are found, the module organizes the reports by date and time and indicates the completion status at step 908. A report is selected, and a page displayed to the user which outlines the report table of contents, at step 910. If the report is determined complete at step 912, the module retrieves the report at step 914 and presents the graphical and-or textual content of the report at step 916. If the report is not completed, the report can be completed via user command input at step 912. Upon such a request, the module builds the entire report, including text, graphics, and analysis, at step 918. The results are then available to the user at step 916. If additional detailed reporting is desired, the user can “drill down” into the details at step 920, and the module will generate another portion of the report with a finer granularity of detail, at step 922. The more detailed data is then presented to the user at step 924. The new report information will be appended to the original report, and the status changed accordingly, at step 926, if an update is required.

The load test software preferably allows the provider, i.e. the ISP, ASP, web-site developer, or the like, at which the load test service resides, or through which access to the load test service is provided, the ability to conduct billing of the system user, and other administrative tasks, such as account creation, maintenance, or deletion. The account based allocation of the resources ascribed a specific system user is a key feature of the system. This feature allows the system services to be easily used and metered out to system users, and provides a convenient technique for tracking of use of system resources, duration of resource use, billing rate gradations, service restriction allocation, and, ultimately, customer billing data to be exported to a standard billing software system. Flexibility in establishing account types with restrictions of use based on level of service, and an integration of those service restrictions within the use of the system by the system user, is an element of the system for ISPs, ASPs, and web-site developers.

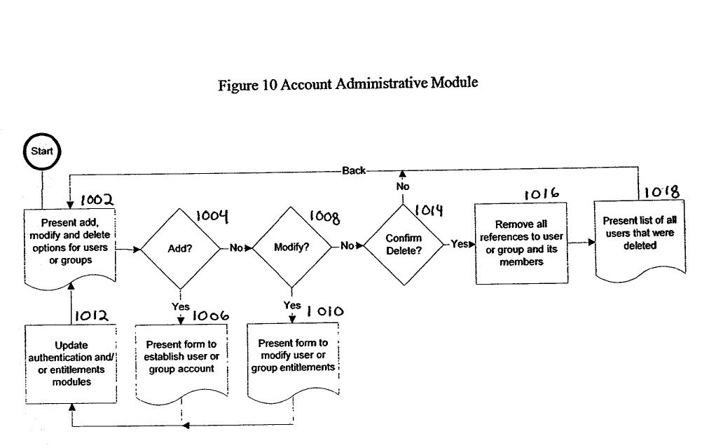

The purpose of the account administration software module is to view a summary of usage statistics and administrate user/group accounts. Administration may be performed locally or remotely. Either the user or the provider can view a summary of usage for the account of interest for at least the current billing time period. This information helps the account administrator determine the service utilization rate so that administrators may predict and plan for service upgrades. Administrative level users of the service provider are entitled to add, modify, or delete individual system user and group accounts as required by the administrative application. FIG. 10 is a flow diagram illustrating the Account Administration software module. Entry is gained to the module by selection of the Administration function on the Main Page. Service provider administration level users are permitted to select account administrative functions at step 1002. Administrators may Add users at step 1004. Administrators would then be presented with a page allowing the addition of either individual or group accounts at step 1006. Administrators may modify existing accounts at step 1008. Administrators modifying accounts would be presented with a page to of all user characteristics, including entitlements of privileges, cost rates, and other allocation of resource restrictions at step 1010. Warnings are provided at each step to ensure that any account information change is not performed inadvertently. Any addition or modification of account information is authenticated and saved at step 1012. Administrators may delete accounts at step 1014. Deletion of a user removes all references to the user at step 1016. A list of deleted users is then presented to the administrator at step 1018. Further, it will be apparent to those skilled in the art that billing may be performed on a per test rate, per line rate, per user rate, per unit time access rate (monthly, annually), or the like.

Those of ordinary skill in the art will recognize that many modifications and variations of the present invention may be implemented. The foregoing description and the following claims are intended to cover all such modifications and variations.

What is claimed is:

1. A software load tester, comprising:
a remote access connection to at least one provider, wherein said remote access connection is accessible to at least one remote user and to at least one remote site;
a plurality of load test resources resident at the at least one provider; and
at least one account recorder, wherein said at least one account recorder governs access by the at least one user to said plurality of load test resources.

2. The software load tester of claim 1, further comprising a use-recorder that records activity on the at least one remote site by the at least one user granted access to the at least one remote site according to said account recorder, wherein the recorded activity is at least one of said plurality of load test resources.

3. The software load tester of claim 2, wherein the recorded activity is recorded in accordance with at least one recordation instruction from the at least one user granted access to the at least one remote site according to said account recorder

4. The software load tester of claim 2, further comprising a playback unit, wherein said playback unit plays back the recorded activity according to at least one playback instruction from the at least one user granted access to the at least one remote site according to said account recorder.

5. The software load tester of claim 1, wherein said account recorder governs access by requiring entry by the at least one user granted access to the at least one remote site according to said account recorder of at least one identification item selected from the group consisting of a username, a password, an account code, an encryption key, and a cookies.

6. The software load tester of claim 1, further comprising a load test manager, wherein the at least one user granted access to the at least one remote site according to said account recorder enters a plurality of load test information to said load test manager in order to execute at least one load test using said plurality of load test resources.

7. The software load tester of claim 6, further comprising a remote access browser receiver that receives the plurality of load test information via multiple browser types and platforms.

8. The software load tester of claim 7, wherein the plurality of load test information includes at least arrival rates to the remote site of interest, wherein the arrival times are selected from the group consisting of linear, exponential, Poisson, and non-deterministic distributions.

9. The software load tester of claim 7, wherein the plurality of load test information includes at least user types to the remote site of interest, wherein the user types are selected from a plurality of recorded activity.

10. The software load tester of claim 7, wherein the plurality of load test information includes at least user tolerances for the remote site of interest, wherein the user tolerances are selected from the group consisting of high, medium, and low patience with misperformance of the remote site of interest.

11. The software load tester of claim 7, wherein the plurality of load test information includes at least user access port speeds.

12. The software load tester of claim 7, wherein the plurality of load test information includes at least user browser type.

13. The software load tester of claim 1, further comprising a scheduler, wherein said scheduler schedules access by a plurality of users to said plurality of load test resources.

14. The software load tester of claim 1, further comprising a performance appraiser communicatively connected to said plurality of load test resources, wherein said performance appraiser outputs a plurality of performance characteristics of the one of the at least one remote site that is subjected to said plurality of load test resources.

15. A method of software load testing, comprising:
remotely connecting at least one provider to at least one remote user and to at least one remote site;
providing a plurality of load test resources resident at the at least one provider;
governing access by the at least one user to the plurality of load test resources; and
load testing the at least one remote site upon receipt of a direction to load test from the at least one remote user granted access according to said governing access, wherein said load testing comprises a subjecting of the at least one remote site to at least one of the plurality of load test resources.

16. The method of claim 15, further comprising recording activity on the at least one remote site by the at least one user granted access to the at least one remote site.

17. The method of claim 16, further comprising receiving at least one recordation instruction from the at least one user granted access the at least one remote site, and wherein said recording is in accordance with the at least one recordation instruction.

18. The method of claim 16, further comprising playing back the recorded activity.

19. The method of claim 18, further comprising receiving at least one playback instruction from the at least one user granted access to the at least one remote site, wherein said playing back is in accordance with the at least one playback instruction.

20. The method of claim 15, wherein said governing access comprises requiring entry by the at least one user granted access to the at least one remote site, prior to said load testing, of at least one identification item selected from the group consisting of a username, a password, an account code, an encryption key, and a cookies.

21. The method of claim 15, further comprising managing said load testing, wherein said managing is in accordance with a plurality of load test information received from the at least one user granted access to the at least one remote site.

22. The method of claim 15, further comprising scheduling access by a plurality of users to said load testing.

23. The method of claim 22, wherein said scheduling comprises scheduling at least one of the plurality of load test resources of the at least one provider.

24. The method of claim 22, wherein said scheduling comprises scheduling at least one of a second plurality of load test resources of at least one outside party, wherein the second plurality comprises line capacity.

25. The method of claim 15, further comprising outputting a plurality of performance characteristics of the at least one remote site that is subjected to said load testing.
